(19) United States
(12) Patent Application Publication
(10) Pub. No.: US 2010/0100202 A1
(43) Pub. Date: Apr. 22, 2010

(54) Method and Related Apparatus for Controlling Operating Mode of a Portable Electronic Device

(76) Inventors: Chi-Chin Chen, Taipei Hsien (TW); Chih-Hsin Wang, Taipei Hsien (TW); Mu-Chen Chiu, Taipei Hsien (TW); Yao-Ren Chang, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 12/499,071

(22) Filed: Jul. 7, 2009

(30) Foreign Application Priority Data
Oct. 20, 2008 (TW) 097140195

(51) Int. Cl. G05B 15/00; G01R 33/00

(52) U.S. Cl. 700/75; 324/200

(57) ABSTRACT

A method for controlling an operating mode of a portable electronic device having a first plane and a second plane connected together comprises forming a magnet in the first plane, forming a magnetic flux sensor in a position of the second plane corresponding to the magnet for sensing magnetic flux, and controlling the operating mode of the portable electronic device according to the sensing result of the magnetic flux sensor.

### BACKGROUND OF THE INVENTION

1. Field of the Invention

The present invention is related to a method and related apparatus for controlling operating modes of a portable electronic device, and more particularly, to a method and related apparatus for controlling operating modes capable of enhancing convenience and efficiency of powering on the portable electronic device.

2. Description of the Prior Art

A notebook computer has advantages of small size, lightweight, portability, etc, and allows a user to work outside an office, to access functions of the computer systems, and no longer to be bounded in front of a desk. Convenience and portability of the notebook computer allow the user to have powerful computation and documentation abilities, and enjoy complete multimedia functions anytime and anywhere.

Please refer to FIG. 1, which is a schematic diagram of a notebook computer system 10 in the prior art. In general, the notebook computer system 10 is composed of a lid 100 and a chassis 102, which are connected by a roller 104. The lid 100 comprises a display screen, camera, etc, and the chassis 102 comprises a keyboard, touch panel, power switch, host, expanding interface, etc. When using the notebook computer system 10, the user has to open the lid 100, and turn on the power switch, so as to power on the host. The operations—open the lid 100, and turn on the power switch—obviously lack efficiency, because the user definitely wants to use the notebook computer system 10 when opening the lid 100. However, in the prior art, the user has to “open the lid 100, and turn on the power switch”, to use the notebook computer system 10, lacking efficiency obviously.

In order to improve the aforementioned disadvantages, TWN Patent application NO. 096145940 discloses a method and related apparatus for controlling operating modes of a portable electronic device, which uses a gravity acceleration sensor (abbreviated as G-sensor), to obtain an angle corresponding to a plumb line (i.e. absolute angle), so as to determine whether the lid of the notebook computer is open. However, using the aforementioned method, except cost of the G-sensor, a designer has to take many aspects into consideration, because the G-sensor can only sense the angle corresponding to the plumb line, which increases design complexity.

Therefore, how to improve the power-on method of the notebook computer has been one of the subjects in the industry.

### SUMMARY OF THE INVENTION

It is therefore a primary objective of the claimed invention to provide a method and related apparatus for controlling operating modes of a portable electronic device.

The present invention discloses a method for controlling operating modes of a portable electronic device, which has a first plane and a second plane connected together. The method comprises forming a magnet in the first plane, forming a magnetic flux sensor in a position of the second plane corresponding to the magnet for sensing magnetic flux, and controlling the operating modes of the portable electronic device according to a sensing result of the magnetic flux sensor.

The present invention further discloses a device for controlling operating modes of a portable electronic device, which has a first plane and a second plane connected together. The device comprises a magnet, formed in the first plane, a magnetic flux sensor, formed in a position of the second plane corresponding to the magnet, for sensing magnetic flux, and a control unit, coupled to the magnetic flux sensor and a host of the portable electronic device, for controlling the operating modes of the portable electronic device according to a sensing result of the magnetic flux sensor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic diagram of a notebook computer system in the prior art.

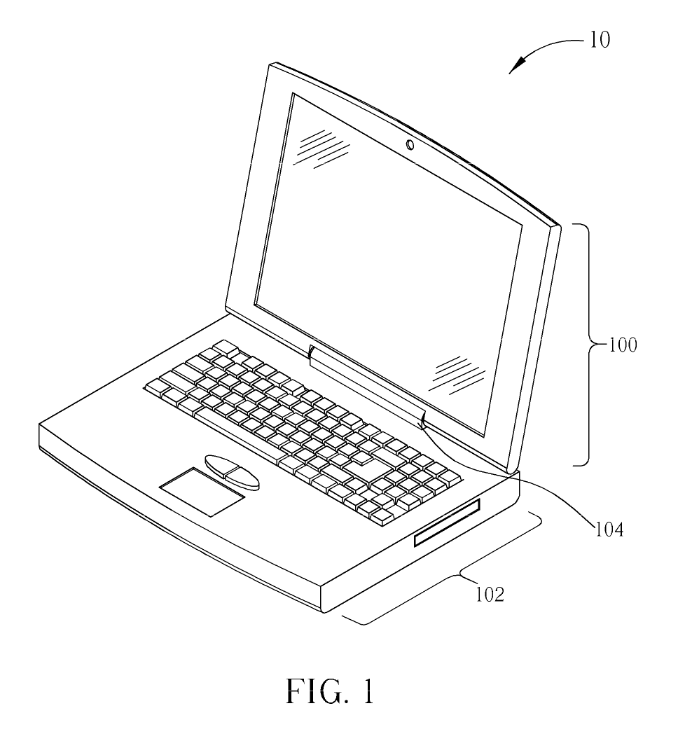

FIG. 2 is a schematic diagram of a process according to an embodiment of the present invention.

FIG. 3 is a schematic diagram of a notebook computer system according to an embodiment of the present invention.

FIG. 4 is a block diagram of a device for controlling operating modes shown in FIG. 3.

FIG. 5A illustrates a schematic diagram of a gravity acceleration sensor shown in FIG. 3 according to an embodiment of the present invention.

FIG. 5B illustrates a schematic diagram of operations of a gravity acceleration sensor shown in FIG. 3.

### DETAILED DESCRIPTION

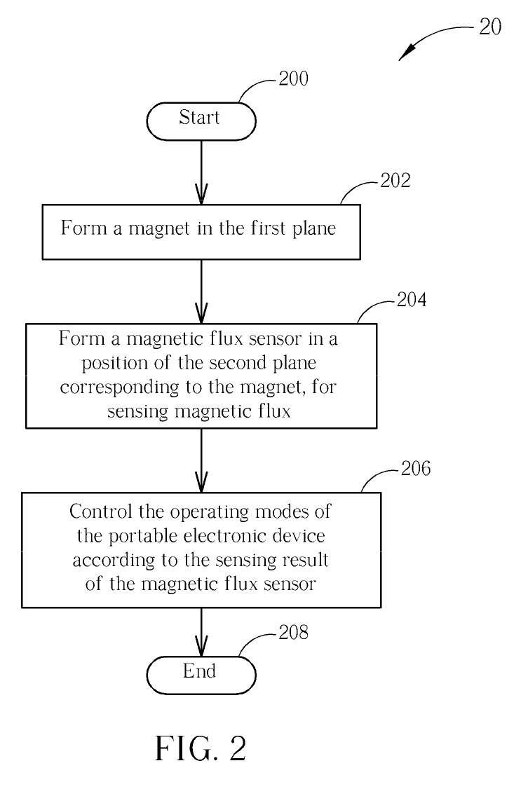

Please refer to FIG. 2, which is a schematic diagram of a process 20 in accordance with an embodiment of the present invention. The process 20 is utilized for controlling operating modes of a portable electronic device. The portable electronic device is preferably a notebook computer, which has a first plane and a second plane connected together. The process 20 comprises the following steps:

Step 200: Start.

Step 202: Form a magnet in the first plane.

Step 204: Form a magnetic flux sensor in a position of the second plane corresponding to the magnet, for sensing magnetic flux.

Step 206: Control the operating modes of the portable electronic device according to the sensing result of the magnetic flux sensor.

Step 208: End.

According to the process 20, the present invention respectively forms a magnet and a magnetic flux sensor in these two planes (lid and chassis), and determines whether the lid of the portable electronic device is open according to the magnetic flux sensed by the magnetic flux sensor, so as to control the operating modes of the portable electronic device.

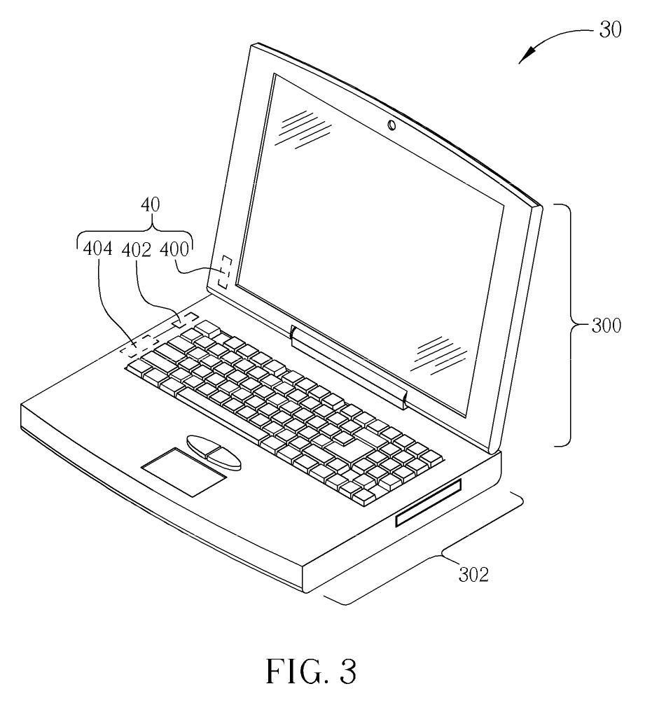

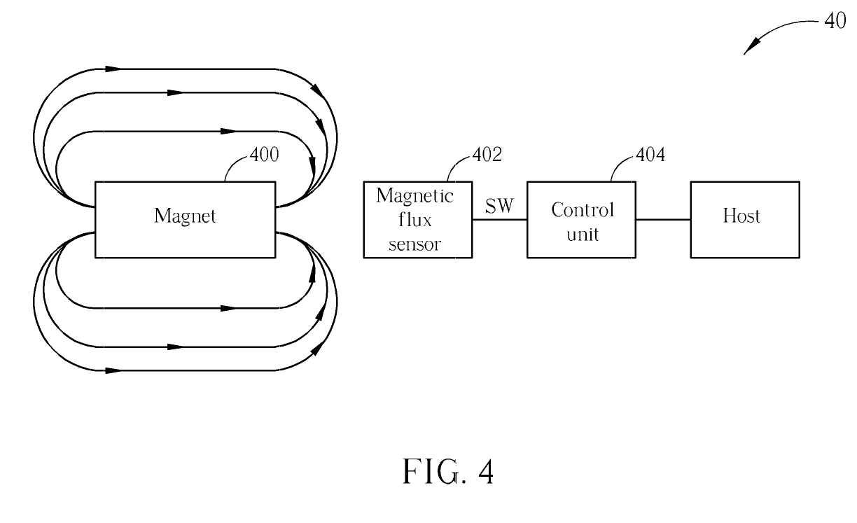

In order to clearly describe the operations of the present invention, please continue to refer to FIG. 3, which is the schematic diagram of a notebook computer system 30 according to an embodiment of the present invention. The notebook computer system 30 is designed based on the process 20, and comprises a lid 300, a chassis 302 and a device for controlling the operating modes 40. The lid 300 comprises the display screen, camera, etc, and the chassis 302 comprises the keyboard, touch panel, power switch, host, expanding interface, etc. Please continue to refer to FIG. 4, which is the block diagram of the device for controlling the operating modes 40. The device for controlling the operating modes 40 comprises a magnet 400, a magnetic flux sensor 402 and a control unit 404. The magnet 400 is preferably a permanent magnet, and is formed in the lid 300 of the notebook computer system 30. The magnetic flux sensor 402 is formed in a position of the chassis 302 corresponding to the magnet 400, for sensing magnetic flux of the magnet 400, so as to generate a switch signal SW to the control unit 404. The control unit 404 is coupled to the magnetic flux sensor 402 and the host of the notebook computer system 30, for controlling operation modes of the notebook computer system 30 according to the switch signal SW outputted by the magnetic flux sensor 402.

Simply speaking, with the change of the distance between the magnet 400 and the magnetic flux sensor 402, magnetic lines of force (magnetic flux) which pass through the magnetic flux sensor 402 change, i.e. the magnetic flux sensed by the magnetic flux sensor 402 is getting more when the distance between the magnet 400 and the magnetic flux sensor 402 gets closer, and the magnetic flux sensed by the magnetic flux sensor 402 is getting less when the distance between the magnet 400 and the magnetic flux sensor 402 gets longer. Therefore, the sensing result of the magnetic flux sensor 402 can correspond to the distance between the lid 300 and the chassis 302, so as to determine whether the lid 300 is open, for controlling the operating modes of the notebook computer system 30.

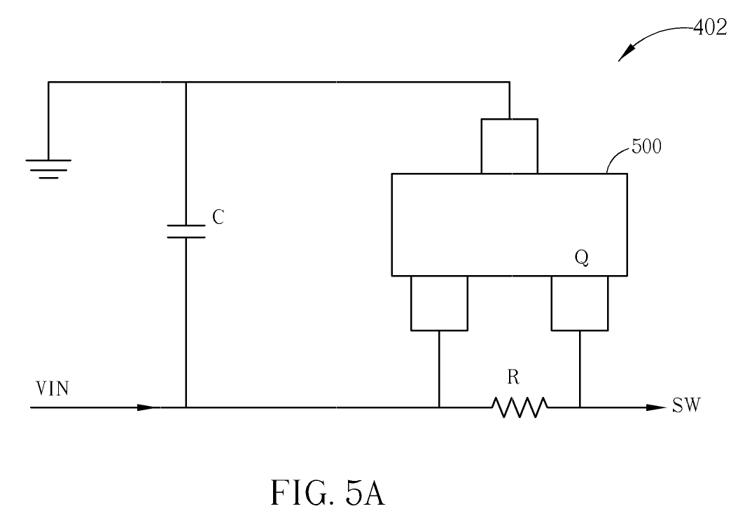

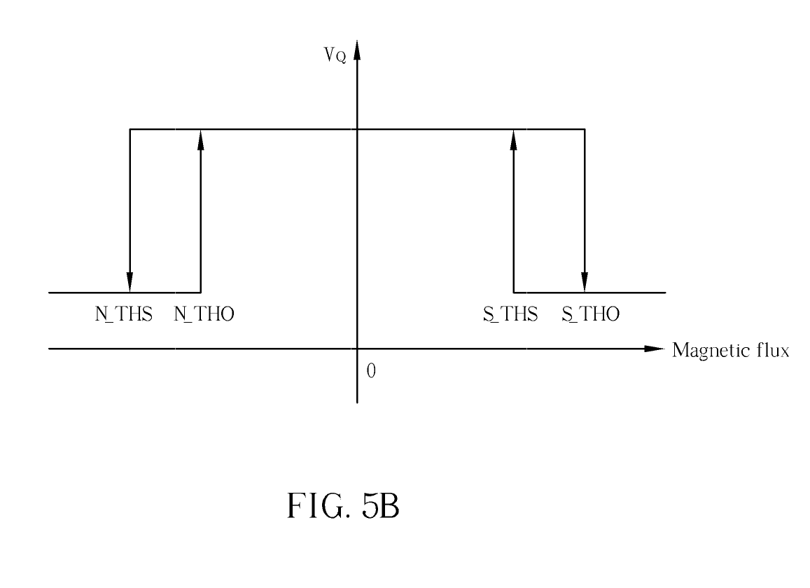

Please notice that, through sensing the magnetic flux of the magnet 400 by the magnetic flux sensor 402, the present invention controls the operating modes of the notebook computer system 30; wherein the components of the magnetic flux sensor 402 are broadened, and are acceptable if the components of the magnetic flux sensor 402 can sense the magnetic flux of the magnet 400. For example, please refer to FIG. 5A and FIG. 5B, FIG. 5A is a schematic diagram of the magnetic flux sensor 402 according to an embodiment of the present invention, and FIG. 5B is a schematic diagram of operations of the magnetic flux sensor 402. In FIG. 5A, the magnetic flux sensor 402 is composed of a switch device 500, a resistor R and a capacitor C. The switch device 500 is a device with 3 terminals, and is coupled to a voltage VIN, a ground and the control unit 404, for switching an output voltage V_{Q} of a terminal Q according to the magnetic flux of the magnet 400, so as to generate the switch signal SW to the control unit 404. In FIG. 5B, the vertical axis represents the output voltage V_{Q}, and the horizontal axis represents the magnetic flux sensed by the switch device 500, wherein the magnetic flux is referred to the quantity of magnetic lines of force which pass through the magnetic flux sensor 402. That is to say, the magnetic flux must be greater than or equal to 0. In this case, in order to represent the magnetic flux with different poles, in FIG. 5B, the left side of the vertical axis represents the magnetic flux of N pole of the magnet 400, and the right side of the vertical axis represents the magnetic flux of S pole of the magnet 400. That is to say, when N pole of the magnet 400 face the magnetic flux sensor 402, operations of the magnetic flux sensor 402 correspond to the left side of the vertical axis in FIG. 5B; when S pole of the magnet 400 face the magnetic flux sensor 402, operations of the magnetic flux sensor 402 correspond to the right side of the vertical axis in FIG. 5B. Therefore, as illustrated in FIG. 5B, when the magnet flux sensed by the magnetic flux sensor 402 increases from 0 toward right or left direction (depends on the pole of the magnet 400) to a threshold value S_THS or N_THS, this case represents that the distance between the lid 300 and chassis 302 decreases, i.e. the user is closing the lid 300. On the contrary, when the magnet flux sensed by the magnetic flux sensor 402 decreases from a high value to a threshold value S_THO or N_THO, this case represents that the distance between the lid 300 and chassis 302 increases, i.e. the user is opening the lid 300.

Therefore, based on the sensing results of the magnetic flux sensor 402, the control unit 404 can determine whether the user open the lid 300, so as to determine whether the user want to use the notebook computer system 30. Of course, methods used by the control unit 404 for controlling operations of the notebook computer system 30 are broadened, and those skilled in the art can design the control flow based on system requirements. Here are 4 examples:

First case, the notebook computer system 30 is operated in a power-off mode (or sleep mode) in the beginning, and the lid 300 is close. When the magnetic flux sensed by the magnetic flux sensor 402 decreases to the threshold value S_THO or N_THO, this case represents that the lid 300 is being opened, and the control unit 404 can control the notebook computer system 30 into a power-on mode.

Second case, the notebook computer system 30 is operated in a power-on mode in the beginning, and the lid 300 is close. When the magnetic flux sensed by the magnetic flux sensor 402 decreases to the threshold value S_THO or N_THO, this case represents that the lid 300 is being opened, and the control unit 404 can maintain the power-on mode of the notebook computer system 30.

Third case, the notebook computer system 30 is operated in the power-on mode in the beginning, and the lid 300 is open. When the magnetic flux sensed by the magnetic flux sensor 402 increases to the threshold value S_THS or N_THS, this case represents that the lid 300 is being closed, and the control unit 404 can control the notebook computer system 30 into the power-off mode (or sleep mode).

Fourth case, the notebook computer system 30 is operated in the power-off mode (or sleep mode) in the beginning, and the lid 300 is open. When the magnetic flux sensed by the magnetic flux sensor 402 increases to the threshold value S_THS or N_THS, this case represents that the lid 300 is being closed, and the control unit 404 can maintain the power-off mode (or sleep mode) of the notebook computer system 30.

Notice that, the aforementioned 4 examples is just used for explaining the idea of the present invention. Those skilled in the art can accordingly modify the control flow, which is not limited in these 4 examples.

Furthermore, in the notebook computer system 30, the magnet 400 is formed in the lid 300, and the magnetic flux sensor 402 is formed in the chassis 302. Actually, the contrary configuration is applicable; that is, the magnet 400 is formed in the chassis 302, and the magnetic flux sensor 402 is formed in the lid 300.

In the prior arts, when the user wants to use the notebook computer system, the user has to open the lid, and then push the power switch. Those kinds of operations lack of efficiency, and do not conform to the operating logic. On the contrary, in the present invention, when the user wants to use the notebook computer system, the user only needs to open the lid. Therefore, the present invention can obviously improve efficiency of powering on the notebook computer system.

To sum up, the present invention respectively forms the magnet and the magnetic flux sensor in the lid and the chassis of the portable electronic device, so as to determine whether the lid of the portable electronic device is open according to the magnetic flux sensed by the magnetic flux sensor, and control the operating modes of the portable electronic device accordingly. Therefore, the present invention is not only capable of improving the convenience, but also the power-on efficiency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for controlling operating modes of a portable electronic device having a first plane and a second plane connected together, the method comprising:
forming a magnet in the first plane;
forming a magnetic flux sensor in a position of the second plane corresponding to the magnet for sensing magnetic flux; and
controlling the operating modes of the portable electronic device according to a sensing result of the magnetic flux sensor.

2. The method of claim 1, wherein the portable electronic device is operated in a first mode.

3. The method of claim 2, wherein controlling the operating modes of the portable electronic device according to the sensing result of the magnetic flux sensor comprises:
controlling the portable electronic device to operate in a second mode when the magnetic flux sensed by the magnetic flux sensor increases to a first threshold value.

4. The method of claim 3, wherein the first mode is a power-off mode, and the second mode is a power-on mode.

5. The method of claim 3, wherein the first mode is a sleep mode, and the second mode is a power-on mode.

6. The method of claim 3, wherein the first mode and the second mode are both power-on modes.

7. The method of claim 2, wherein controlling the operating modes of the portable electronic device according to the sensing result of the magnetic flux sensor comprises:
controlling the portable electronic device to operate in a third mode when the magnetic flux sensed by the magnetic flux sensor decreases to a second threshold value.

8. The method of claim 7, wherein the first mode is a power-on mode, and the third mode is a power-off mode.

9. The method of claim 7, wherein the first mode is a power-on mode, and the third mode is a sleep mode.

10. The method of claim 7, wherein the first mode and the second mode are both power-off modes.

11. The method of claim 7, wherein the first mode and the second mode are both sleep modes.

12. The method of claim 1, wherein the portable electronic device is a notebook computer.

13. The method of claim 12, wherein the first plane is a lid, and the second plane is a chassis.

14. The method of claim 12, wherein the first plane is a chassis, and the second plane is a lid.

15. A device for controlling operating modes of a portable electronic device having a first plane and a second plane connected together, the device comprising:
a magnet, formed in the first plane;
a magnetic flux sensor, formed in a position of the second plane corresponding to the magnet, for sensing magnetic flux; and
a control unit, coupled to the magnetic flux sensor and a host of the portable electronic device, for controlling the operating modes of the portable electronic device according to a sensing result of the magnetic flux sensor.

16. The device of claim 15, wherein the portable electronic device is operated in a first mode.

17. The device of claim 16, wherein the control unit is utilized for controlling the portable electronic device to operate in a second mode when the magnetic flux sensed by the magnetic flux sensor increases to a first threshold value.

18. The device of claim 17, wherein the first mode is a power-off mode, and the second mode is a power-on mode.

19. The device of claim 17, wherein the first mode is a sleep mode, and the second mode is a power-on mode.

20. The device of claim 17, wherein the first mode and the second mode are both power-on modes.

21. The device of claim 16, wherein the control unit is utilized for controlling the portable electronic device to operate in a third mode when the magnetic flux sensed by the magnetic flux sensor decreases to a second threshold value.

22. The device of claim 21, wherein the first mode is a power-on mode, and the third mode is a power-off mode.

23. The device of claim 21, wherein the first mode is a power-on mode, and the third mode is a sleep mode.

24. The device of claim 21, wherein the first mode and the second mode are both power-on modes.

25. The device of claim 21, wherein the first mode and the second mode are both sleep modes.

26. The device of claim 15, wherein the portable electronic device is a notebook computer.

27. The device of claim 26, wherein the first plane is a lid, and the second plane is a chassis.

28. The device of claim 26, wherein the first plane is a chassis, and the second plane is a lid.
